(19) United States
(12) Patent Application Publication
(10) Pub. No.: US 2018/0294234 A1
(43) Pub. Date: Oct. 11, 2018

(54) MODULE AND METHOD OF A SELECTIVE ELECTRONIC-MAGNETIC INTERFERENCE SHIELDING

(71) Applicant: Ming-Che WU, Nantou County (TW)

(72) Inventor: Ming-Che WU, Nantou County (TW)

(21) Appl. No.: 15/816,213

(22) Filed: Nov. 17, 2017

(30) Foreign Application Priority Data
Apr. 10, 2017 (TW) 106111894

(51) Int. Cl. H01L 23/552; H01L 23/31; H01L 21/3205

(52) U.S. Cl. CPC H01L 23/552; H01L 21/268; H01L 21/32051; H01L 23/3121

(57) ABSTRACT

Module and method of a selective electronic-magnetic interference shielding includes a substrate, at least a first electronic element deployed on a principle surface of the substrate, an mold resin covering the first electronic element, and an electronic-magnetic interference shielding, wherein the mold resin has a mold surface relatively far above the substrate and is divided into a central area and an outer area surrounding the central area. The mold resin installs a trench between the central area and the outer area, the trench forms a closed route enfolding the first electronic element, and the electro-magnetic interference shielding distributes over the central area and the trench. Therefore the module and method of a selective electronic-magnetic interference shielding is adaptable to various required designs with lower manufacturing cost.

### BACKGROUND OF THE INVENTION

### Field of the Invention

The present invention relates to a semiconductor encapsulating packaging and, more particularly to a module and method of electronic-magnetic interference shielding (EMI Shielding) which is adaptable to multi-functional integration for semiconductor encapsulating package.

### Description of the Related Art

Recent year as the rapid growth in technology, user need for portable and convenient products blows the trend of electronics toward thinner, lighter, and multi-functional designs. Accordingly, the technology of semiconductor encapsulating package is under the progress of minimization in limited volume to achieve high-efficient calculation and multi-functional integration

To avoid the electronic-magnetic interference dispersed by the electronic elements, a metal cover as for the EMI shielding was disposed on the traditional semiconductor encapsulating package. However, because the metal cover occupied quite a lot of space, in order to shrank the space and volume the industry therefore developed a brand new conformal EMI shielding by way of sputtering or coating conductive magnetic materials over the surrounding of the mold resin acting as the EMI shielding of the semiconductor encapsulating packaging.

However, there might be electronic interference between two electronic elements on a single substrate, the industry then developed a compartment EMI shielding technology by way of cutting a trench inside the mold resin and then filling in with the conductive material as the EMI shielding.

### SUMMARY OF THE INVENTION

To achieve previous purpose, present invention provides a module and method of a selective electronic-magnetic shielding includes a substrate, at least a first electronic element deployed on a principle surface of the substrate, and a mold resin disposed on the principle surface sealing an electronic element. Wherein the mold resin has a mold surface which is relatively far above the substrate, the mold surface divided into a central area and an outer area surrounding the central area, the mold resin has a trench between the central area and the outer area, the trench forms a closed route surrounding the first electronic element, and an electronic-magnetic interference shielding is made of conductive magnetic material scattering over the central area and the trench.

Present invention further provides a module and method of a selective electro-magnetic interference shielding which steps including: prepare a substrate, at least a first electronic element, and a mold resin package, divide the mold surface of the mold resin into a central area and an outer area which is relatively far above the substrate, and a mold surface between the central area and the outer area, form a closed route to the substrate's projection on the mold surface of the encapsulating package and seal the first electronic element; laser cut a trench along the working area and coat the conductive material on the central area and the trench to form an electronic-magnetic interference shielding.

Therefore, the present invention only requires one step to process cutting and coating of the electronic-magnetic interference shielding, the procedure is quite simple and is especially adaptable for multi-functional integration in encapsulating module.

### BRIEF DESCRIPTION OF THE DRAWINGS

FIG. 1 is an external perspective view of the module of the present invention.

FIG. 2 is a top view of a laser-cut finishing module of the present invention.

FIG. 3 is a top view of a paint-coated finishing module of the present invention.

FIG. 4 is a cross-sectional view of the module taken along 4-4 in FIG. 3.

### DETAILED DESCRIPTION OF PREFERRED EMBODIMENTS

To specifically illustrate the embodiment and efficiency of the present invention, the description may be depicted with drawing as following:

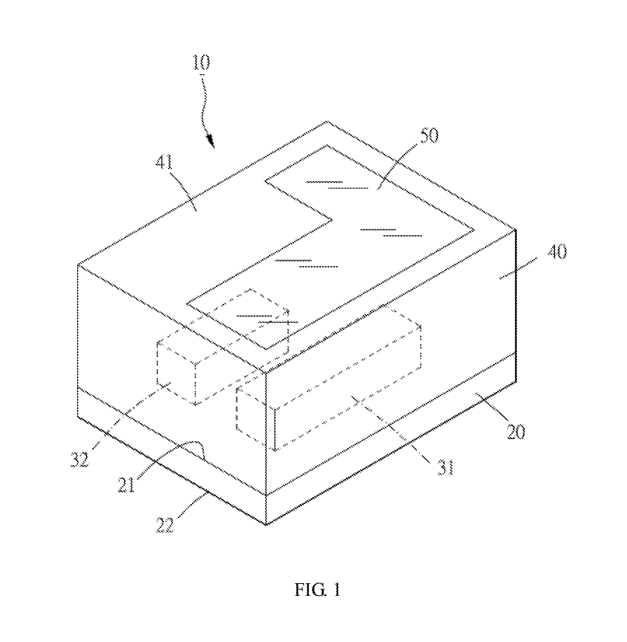

As shown in FIG. 1-4, the present invention provide a module of encapsulating packaging 10 mainly composes of a substrate 20, a plurality of electronic elements 31, 32, a mold resin 40 and an electronic-magnetic interference shielding 50. The substrate 20 is a multi-tier circuit having a principle surface 21 and a connecting surface 22. The substrate 20 is square shape in this embodiment so it is easy to indicate the X-Y-Z coordinate. Wherein the direction of X, Y, and Z are individually show the length, the width, and the height direction of the substrate 20. The previous directions are defined for easy recognition and is prevalently appreciated by those skilled in the art.

A plurality of electronic elements comprises the first electronic element 31 and the second electronic element 32, said electronic elements 31, 32 is deployed on the principle surface 21 of the substrate 20 by the Surface Mount Technology (SMT). As for the connecting surface 22 of the substrate 20 may be installed with several solder pad 33 (Figs. are not shown) as the signal input/ output interface of the electronic element 31 and 32. Besides, the substrate 20 is made of copper foil and is conductively connected to the inner ground layer of the substrate (Figs. are not shown).

The mold resin 40 is usually made of epoxy resin of insulation material, installs on the principle surface 21, and seals the electronic element 31 and 32. In this embodiment, the mold resin 40 is a cubic having a four dimensional surfaces in connection to the substrate 20, and a mold surface 41 disconnects to the substrate 20, the mold surface 41 is relatively far above the substrate 20 along the Z direction.

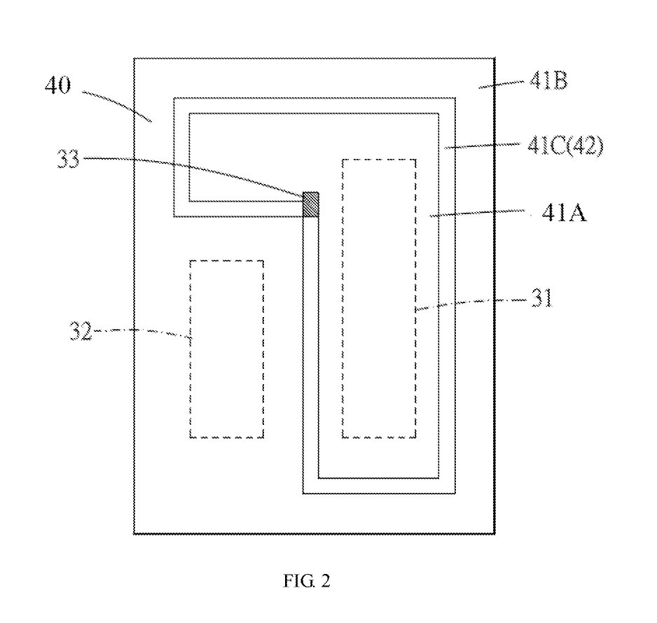

As shown in FIG. 2, the mold surface 41 of the mold resin 40 is square shape and may be divided into a central area 41A and an outer area 41B surrounding the central area, and a working area 41C locates between the central area 41A and the outer area 41B. The mold surface 41 faces to the projection of the substrate 20 and forms a closed route surrounding the first electronic element 31 along the Z direction. In this embodiment, the outer area 41B completely not overlap the edge of the mold surface 41, in other embodiment, the outer area 41B may overlap the edge of the mold surface 41. Besides, the second electronic element 32 always keeps clear of the closed route.

The working area 41C as for shielding path of laser cutting. The laser cutting may use the material such as Carbonic acid gas (CO2) or Yttrium Aluminum Garnet (YAG) etc., It takes one time or multiple times to scan and process along the working area 41C at predetermined power to form the trench 42 having the width and the depth basically the same.

In this embodiment, the solder pad 33 is disposed on the working area 41C facing to the substrate's projection, therefore when the trench 42 is finished by laser cutting, the solder pad 33 may be exposed on the bottom of the trench 42.

When the laser cutting is finished, the conductive material is coated on the central area 41A and filled in the trench 42 to complete the process of electronic-magnetic interference shielding 50.

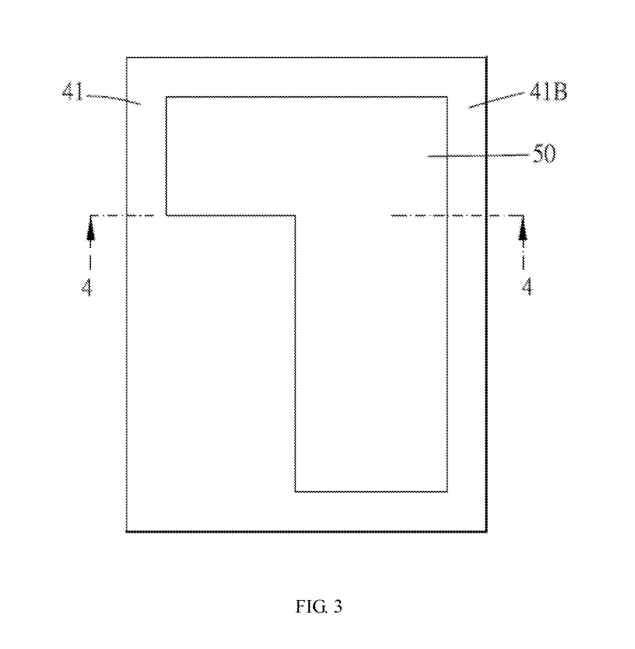

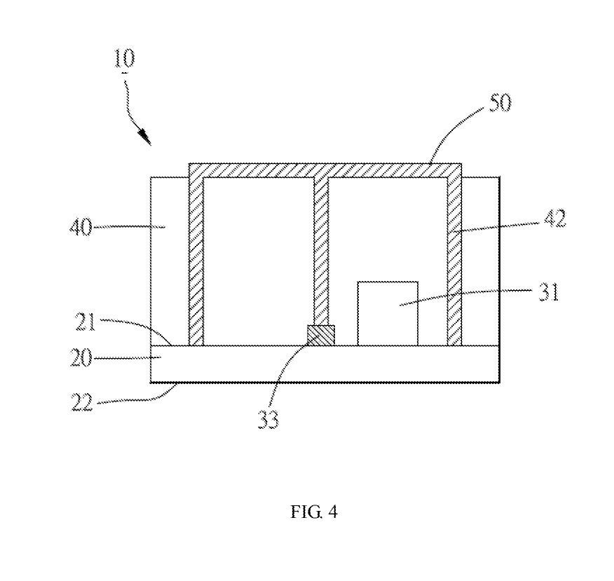

As shown in FIG. 3 and FIG. 4, because the electronic-magnetic interference shielding 50 has completed cover the first electronic element 31 and actually grounded through the solder pad 33, so the second electronic element 32 is well shielded and effectively isolated from the influence of electronic-magnetic interference shielding 50.

Therefore, the present invention may selectively provide the electronic-magnetic interference shielding to the electronic elements and waive away intricate manufacturing procedure as long as defining the working area before three steps laser cutting and coating.

Apart from grounding through the solder pad 33 as revealed in previous embodiment, the electronic-magnetic interference shielding 50 of the present invention may selectively adopt the pulsed laser deposition (PLD) of physical or chemical deposition to form the grounding route of the electronic-magnetic interference shielding 50 and not be limited to the foul's of using solder pad in previous embodiment. At the same time, the shape of working area is merely for exemplifying purpose and may be necessarily alter by those skilled in the art.

What is claimed is:

1. A module of selective electronic-magnetic interference shielding comprises:
a substrate, having a principle surface;
at least a first electronic element, deployed on the principle surface;
a mold resin applies on the principle surface, and seals the first element, wherein the mold resin has a mold surface relatively far above the substrate, the mold surface may be divided into a central area and the outer area surrounding the central area, the mold resin installs a trench between the central area and the outer area, the trench forms a closed route surrounding the first electronic element; and
a selective electronic-magnetic interference shielding is made of conductive magnetic material distributing over the central area and the trench.

2. The module of a selective electronic-magnetic interference shielding of claim 1, wherein the trench is shaped by laser cutting.

3. The module of a selective electronic-magnetic interference shielding of claim 1, wherein the electronic-magnetic interference shielding is processed by coating.

4. The module of a selective electronic-magnetic interference shielding of claim 1, wherein the principle surface has at least a solder pad on the bottom of the trench.

5. The module of a selective electronic-magnetic interference shielding of claim 1, wherein the substrate has a second electronic element sealed in an area out of a closed route surrounding of the mold resin.

6. A method of selective electro-magnetic interference shielding comprises:
prepare a substrate, at least a first electronic element and a mold resin package, a mold surface of the mold resin relatively far above the substrate which is divided into a central area and an outer area surrounding the central area, the working area forms a closed route along a substrate's projection and surrounds at least a first electronic element, laser cut a trench on the working area, coat conductive magnetic material on the central area, and fill in the trench to form an electronic-magnetic interference shielding.

7. The method of a selective electro-magnetic interference shielding of claim 6, wherein the principle surface has at least a solder pad on the bottom of the trench.

8. The method of a selective electro-magnetic interference shielding of claim 6, wherein the substrate deploys the second electronic element which is sealed in the working area out of the closed route of the mold surface's projection of the mold resin.
